(19) United States
(12) Patent Application Publication
(10) Pub. No.: US 2025/0360679 A1
(43) Pub. Date: Nov. 27, 2025

(54) METHOD FOR PRODUCING A THICK POLYMER FILM ON A SUBSTRATE

(71) Applicant: Commissariat à l'Énergie Atomique et aux Énergies Alternatives, Paris (FR)

(72) Inventors: Pierre Montmeat, Grenoble (FR); Franck Fournel, Grenoble (FR)

(73) Assignee: Commissariat à l'Énergie Atomique et aux Énergies Alternatives, Paris (FR)

(21) Appl. No.: 19/214,424

(22) Filed: May 21, 2025

(30) Foreign Application Priority Data
May 27, 2024 (FR) 2405412

(51) Int. Cl. B29C 65/48; B29C 41/00; B29C 41/12; B29C 41/42; B29K 23/00; B29K 67/00; B29K 77/00; B29L 7/00

(52) U.S. Cl. CPC B29C 65/486; B29C 41/003; B29C 41/12; B29C 41/42; B29K 2023/06; B29K 2023/083; B29K 2023/12; B29K 2067/003; B29K 2077/00; B29L 2007/008

(57) ABSTRACT

A method for producing a polymer film of high thickness on a substrate including the following steps: a) forming a first thermoplastic polymer film on a first substrate, b) forming a second thermoplastic polymer film on a second substrate including a support substrate covered by an anti-adherent layer, c) bonding the second thermoplastic polymer film to the first thermoplastic polymer film, by thermocompression, by applying a creep temperature higher than the glass transition temperature of the first thermoplastic polymer film and of the second thermoplastic polymer film, whereby a third thermoplastic polymer film is obtained, d) separating the first substrate from the second substrate, the third thermoplastic polymer film separating from the anti-adherent layer and remaining bonded to the first substrate.

### CROSS REFERENCE TO RELATED APPLICATIONS

This application claims priority to French application number FR2405412, filed May 27, 2024. The contents of which is incorporated by reference in its entirety.

### TECHNICAL FIELD

The present disclosure generally concerns methods for producing thick polymer films, particularly for microelectronics. Thick polymer films are particularly advantageous for the manufacturing of electronic components, especially when methods comprising photolithography and/or bonding steps are concerned.

### PRIOR ART

Polymers used for the manufacturing of electronic components are generally marketed in the form of a liquid formulation. To thus obtain a solid, continuous polymer film, formulations can be spread on the substrate by spin coating, after which a heat treatment step is performed to remove the solvent.

The formulation is selected according to the polymer and to the desired thickness range. The thickness range depends on the viscosity of the liquid formulation and on the spin coating speed. These data are provided by the manufacturer. Generally, the obtained films have a thickness in the range from some ten nanometers to several tens of micrometers, and even up to 100 μm for certain polymers.

However, certain applications require stronger polymer film thicknesses. For example, to ensure bonding to a high-relief surface, the film thickness needs to be much greater than the relief of the substrate, in order to encapsulate it properly.

To obtain high thicknesses, it would seem possible to use a highly viscous formulation and/or to decrease the centrifuging speed.

However, in automated industrial equipment, a highly viscous formulation would require high-performance, and thus expensive, pumping systems. Further, pipes would tend to clog very easily. As for the use of a low centrifuging speed, this would lead to a poor homogeneity of the thickness of the polymer film.

On the other hand, repeating the steps of polymer film deposition several times on a same substrate would lead to obtaining a polymer structure inhomogeneous in terms of thickness and in which the solvent would tend to remain trapped at the various polymer film interfaces.

### SUMMARY OF THE INVENTION

There is a need for a method for producing a homogeneous polymer film of high thickness.

This aim is achieved by a method for producing a polymer film of high thickness on a substrate comprising the following steps:
a) forming a first thermoplastic polymer film on a first substrate,
b) forming a second thermoplastic polymer film on a second substrate, the second substrate comprising a support substrate covered by an anti-adherent layer,
c) bonding the second thermoplastic polymer film to the first thermoplastic polymer film, by thermocompression, by applying a creep temperature higher than the glass transition temperature of the first thermoplastic polymer film and of the second thermoplastic polymer film, whereby a third thermoplastic polymer film is obtained,
d) separating the first substrate from the second substrate, the third thermoplastic polymer film separating from the anti-adherent layer and remaining on the first substrate.

According to a specific embodiment, steps b) to d) are repeated one or a plurality of times until a thermoplastic polymer film having the desired thickness is obtained.

According to a specific embodiment, the first thermoplastic polymer film and the second thermoplastic polymer film are selected, independently of each other, from among polyolefin, polyamide, polyethylene terephthalate, or ethylene vinyl acetate copolymer films.

According to a specific embodiment, the first substrate is covered by raised elements, for example chips or pillars, the raised elements preferably having a thickness of at least 80 μm and, even more preferably, of at least 100 μm.

According to a specific embodiment, the method comprises, after step d), a subsequent step of mechanical abrasion, possibly followed by a step of chemical-mechanical abrasion, on the raised elements.

According to a specific embodiment, the anti-adherent layer is a halogenated polymer layer, preferably a fluoropolymer layer.

According to a specific embodiment, the anti-adherent layer is a layer formed of silane compounds, preferably halosilanes, for example a layer of octadecyltrichlorosilane or a layer of perfluorodecyltrichlorosilane.

According to a specific embodiment, the first substrate and/or the support substrate of the second substrate are made of glass or of semiconductor material, for example of silicon.

According to a specific embodiment, the creep temperature is higher by at least 100° C. than the glass transition temperature of the first thermoplastic polymer film and than the glass transition temperature of the second thermoplastic polymer film.

According to a specific embodiment, on the one hand, the adhesion energy between the anti-adherent layer and the third thermoplastic polymer film is smaller by at least 500 mJ/m² than the adhesion energy between the first thermoplastic polymer film and the second thermoplastic polymer film, and on the other hand, the adhesion energy between the anti-adherent layer and the third thermoplastic polymer film is smaller by at least 500 mJ/m² smaller than the adhesion energy between the first substrate and the third thermoplastic polymer film.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A, FIG. 1B, FIG. 1C, FIG. 1D, FIG. 1E, FIG. 1F, and FIG. 1G schematically show different steps of a method for producing a polymer film, according to a specific embodiment of the invention;

FIG. 2A, FIG. 2B, FIG. 2C, FIG. 2D, FIG. 2E, FIG. 2F, and FIG. 2G schematically show different steps of a method for producing a polymer film, according to another specific embodiment of the invention.

The various elements are not necessarily shown to the same scale, to make the drawings easier to read.

### DESCRIPTION OF EMBODIMENTS

The same elements have been designated by the same references in the various figures. In particular, structural and/or functional elements common to the different embodiments may have the same references and may have identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings or to a structure in a normal position of use.

Unless specified otherwise, the expressions “about”, “approximately”, “substantially”, and “in the order of” signify plus or minus 10% or 10°, preferably of plus or minus 5% or 5°.

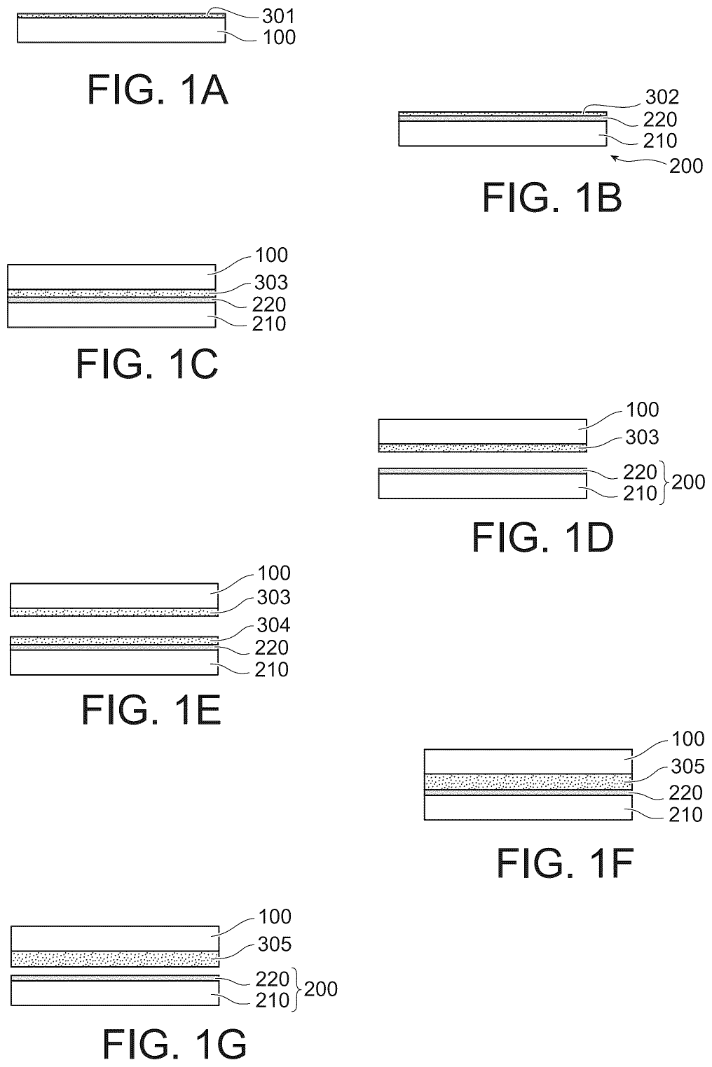

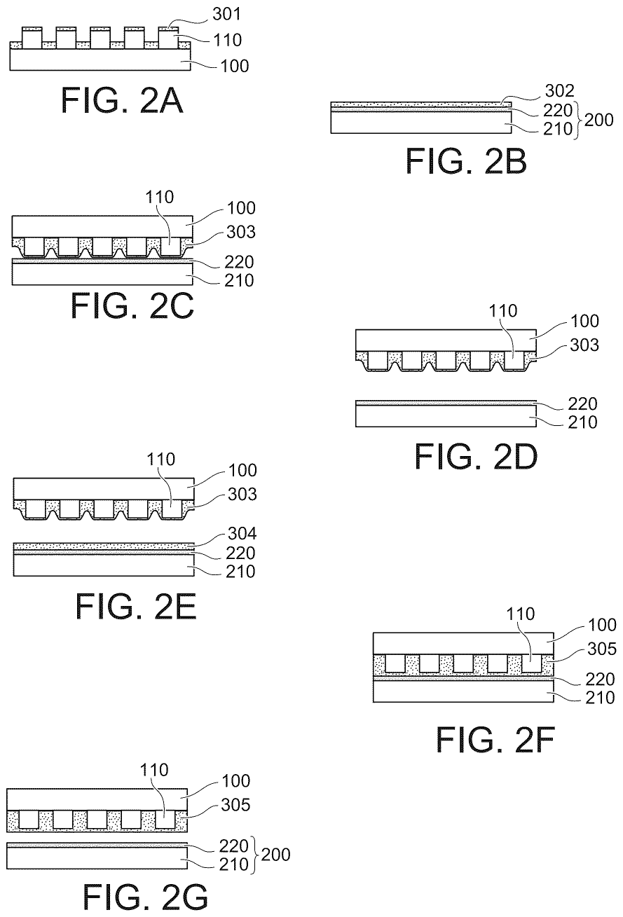

The method for producing a thick polymer film will now be described in greater detail, with reference to FIGS. 1A to 1G and to FIGS. 2A to 2G.

The method comprises at least the following steps:
a) forming a first thermoplastic polymer film 301 on a first substrate 100, and more particularly on the top surface of the first substrate 100 (FIGS. 1A, 2A),
b) forming a second thermoplastic polymer film 302 on a second substrate 200 comprising a support substrate 210 covered by an anti-adherent layer 220 (FIGS. 1B, 2B),
c) bonding the second thermoplastic polymer film 302 to the first thermoplastic polymer film 301, by thermocompression, by applying a creep temperature higher than the glass transition temperature of the first thermoplastic polymer film 301 and of the second thermoplastic polymer film 302, whereby a third thermoplastic polymer film 303 is obtained (FIGS. 1C, 2C),
d) separating the first substrate 100 from the second substrate 200, the third thermoplastic polymer film 303 separating from the second substrate 200 and remaining on the first substrate 100 (FIGS. 1D, 2D).

The cycle of steps b), c), and d) may be repeated one or a plurality of times until a polymer film 305 having the desired thickness is obtained (FIGS. 1E to 1G and FIGS. 2E to 2G).

A homogeneous polymer film 303, 305 having a very high thickness is thus formed.

The resulting polymer films 303, 305 are thick films. By thick, there is meant that the film thickness is greater than that of a film normally formed in the deposition conditions provided by the manufacturer. For example, by thick, there is meant that the film thickness is at least twice or even three times greater than the thickness of the film provided by the manufacturer. The final thickness of the obtained film will depend on the polymer and on the number of stacked films. The thickness of the obtained films is, for example, greater than or equal to 80 μm, or even greater than or equal to 120 μm, which is in particular the case for polyolefin films. The thickness may range up to values greater than 400 μm or even 600 μm for other polymers.

The spreading parameters (centrifuging speed) provided by the manufacturer can be used for the deposition of each film.

The resulting polymer film 303, 305 differs from a multilayer element by the absence of a film/film or film/solvent interface in its volume. Indeed, the implementation of the step of bonding of the thermoplastic films at a temperature higher than their creep temperatures results in the obtaining of a continuous or even one-piece polymer film 303, 305 of greater thickness.

The first polymer film 301 and the second polymer film 302 may have identical or different thicknesses and/or be made of a same material or of different materials. They are preferably identical. The first polymer film 301 and the second polymer film 302 may comprise one or a plurality of thermoplastic polymers.

The first thermoplastic polymer film 301 and/or the second thermoplastic polymer film 302 may be selected, independently of each other, from among polyolefins (polyethylene (PE) or polypropylene (PP), for example), polyamides (PA), polyethylene terephthalate (PET), and ethylene-vinyl acetate copolymers (EVA).

The first polymer film 301 and the second polymer film 303 may be obtained by depositing, for example by spin coating, a liquid formulation comprising the thermoplastic polymer(s) and one or a plurality of organic solvents on the top surface of the substrate of interest 100 or on the adhesive layer 220 of the second substrate 200. A heat treatment may be carried out after each polymer film deposition to remove the organic solvent(s). The temperature of the heat treatment will be selected according to the solvent.

Liquid formulations may be commercial compositions BrewerBOND® 305 marketed by Brewer Science or Zero Newton TWM12000 Series marketed by TOKYO OHKA KOGYO Co (TOK).

The first substrate 100 is the substrate of interest, that is, the substrate on which the thick polymer film is desired to be formed. The polymer film is formed on the top surface of the first substrate 100.

It should be noted that, by top surface of the first substrate 100 (or first surface of the first substrate 100), there is meant the surface that serves as a deposition base for thermoplastic polymer film 301, as opposed to the so-called bottom surface (or second surface) opposite to the top surface, which is not deposited in the context of this method.

According to a first alternative embodiment, for example shown in FIGS. 1A to 1G, the first substrate 100 has a planar surface and is not covered by any element. The first deposited polymer film 301 is in contact with the first surface of the first substrate 100.

According to a second embodiment, for example shown in FIGS. 2A to 2G, the first surface of the first substrate 100 is covered by raised elements 110. The raised elements 110 are, for example, electronic chips or pillars. Raised elements 110 preferably have a thickness of at least 80 μm and, preferably, at least 100 μm.

Chips 110 may be bonded to the first surface of the first substrate 100 to form a paved structure. By way of illustration, the paved structure may be formed by a 700 μm-thick silicon substrate onto which chips of similar thickness have been bonded.

Pillars 110 may be formed by structuring of the first substrate 100, for example by means of a photolithography step followed by an etching.

The second substrate 200 comprises a support substrate 210 covered by an anti-adherent layer 220. The polymer film is deposited on anti-adherent layer 220.

The first substrate 100 and the support substrate 210 of the second substrate 200 may be made of a semiconductor material, for example, silicon, germanium, for example, a silicon-germanium alloy, or also a III-V semiconductor. It may also be a substrate of silicon-on-insulator (SOI) type.

The first substrate 100 and the support substrate 210 of the second substrate 200 may be made of a same material or of different materials. Preferably, the first substrate 100 and the support substrate 210 of the second substrate 200 are silicon substrates.

The first substrate 100 and the support substrate 210 of the second substrate 200 may have identical dimensions and, in particular, have the same shape and/or the same surface area.

For example, the first substrate 100 and/or support substrate 210 may be circular wafers, preferably made of silicon, having a diameter preferably in the range from 100 to 300 mm, in particular 200 mm.

Anti-adherent layer 220 has anti-adherent properties, and in particular a very low surface energy (typically lower than 20 mJ/m²). It acts as an anti-adherent agent with respect to the bonding of the thermoplastic polymer to substrate 200.

Anti-adherent layer 220 may in particular be selected from:
a layer comprising one or a plurality of halogenated polymers, preferably one or a plurality of fluorinated polymers, such as a polymer resulting from the polymerization of at least one fluorinated monomer, for example, a fluorinated acrylate monomer or a fluorinated ethylenic monomer;
a layer of one or a plurality of silane compounds grafted onto support substrate 210 and, more particularly, a layer obtained by grafting of one or a plurality of halosilane compounds, for example, octadecyltrichlorosilane or perfluorodecyltrichlorosilane.

When support substrate 210 is made of silicon and anti-adherent layer 220 is formed from one or a plurality of halosilane compounds, the halosilane compound(s) will react with the hydroxyl groups spontaneously present on the surface of silicon support substrate 210. The compound(s) are thus irreversibly grafted to the surface of support substrate 210 and provide the second substrate 200 with its anti-adherent character.

Anti-adherent layer 220 may be formed according to the following steps:
an operation of placing into contact of the upper surface of support substrate 210 with a liquid composition comprising one or a plurality of anti-adherent compounds and at least one organic solvent, for example, by spin coating;
a drying operation to evaporate the solvent(s).

During step a), the first thermoplastic polymer film 301 is formed on the top surface of the first substrate 100 (FIGS. 1A, 2A). It is preferably deposited by spin coating.

The first thermoplastic polymer film 301 has a thickness Ep1.

During step b), the second thermoplastic polymer film 302 is formed on the second substrate 200, and more particularly on anti-adherent layer 220. It is preferably deposited by spin coating.

The conditions of the deposition of the second polymer film 302 may be the same as or different from the conditions of deposition of the first polymer film 301.

The second polymer film 302 has a thickness Ep2. The low-wetting nature of anti-adherent layer 220 may result in an inhomogeneous second polymer film 302. For example, de-wetting zones can be observed. However, such inhomogeneities are not disturbing, since at step c), a creeping of the polymer is performed.

Thicknesses Ep1 and Ep2 may be identical or different.

During step c), the first substrate 100 and the second substrate 200 are assembled by bonding the first thermoplastic polymer film 301 and the second thermoplastic polymer film 302 by thermocompression.

This step is carried out at a sufficient temperature and at a sufficient pressure to allow the bonding between the first thermoplastic polymer film 301 and the second thermoplastic polymer film 302. The pressure is, for example, in the range from 6 to 50 kN, preferably from 10 to 50 kN. In particular, the applied temperature is advantageously higher than the glass transition temperatures (called Tg) of thermoplastic polymer(s) 301, 302 and, more specifically, it is higher by at least 100° C. than the highest glass transition temperature. Under pressure and at such a temperature, the thermoplastic polymer(s) become fluid, they creep and create intimate contact between the two polymer interfaces. If necessary, the inhomogeneities and de-wetted zones associated with the spreading of the polymer over the second substrate 200 are corrected. This creeping is in particular possible when the viscosity of the adhesive is lower than 10⁴ Pa·s. A third polymer film 303, formed of the first thermoplastic polymer film 301 and of the second thermoplastic polymer film 302, is thus formed. The third thermoplastic polymer film 303 has a homogeneous thickness. It has a thickness Ep3 such that Ep3=Ep1+Ep2.

At the end of thermocompression bonding step c), an assembly comprising the first substrate 100 and the second substrate 200 between which a thick thermoplastic polymer film 303 is interposed, is obtained. The polymer film is in direct contact with the first substrate 100 and with the anti-adherent layer 220 of the second substrate 200.

Thermoplastic polymer films are adhesive. They bond to the first substrate 100 or to another thermoplastic polymer film, but have a low adhesion to anti-adherent layer 220.

Thus, thermoplastic polymer film 303 bonds more strongly to the first substrate 100 than to the anti-adherent layer 220 of the second substrate 200.

This assembly obtained at step c) is thus formed of three interfaces:
an interface between the first polymer film 301 and the second polymer film 302,
an interface between the first thermoplastic polymer film 301 and the first substrate 100,
an interface between the second thermoplastic polymer film 302 and anti-adherent layer 220.

By choosing a temperature higher than the glass transition temperature of the first polymer film 301 and of the second polymer film 302, a continuity is ensured between the two polymer films 301, 302, and a third homogeneous and solid film 303 is reconstructed. The adhesion E(Pol) of this interface is very high. It is the cohesive energy of the polymer if polymer films 301 and 303 are identical.

The interface between the first polymer film 301 and the first substrate 100 is the polymer spreading interface. Its adhesion is strong E(S1), it is generally smaller than E(Pol).

The interface between the second polymer film 302 and the second substrate 200 has a very low adhesion E(S2). In particular E(S2)<E(S1)−500 mJ/m² and similarly E(S2)<E(Pol)−500 mJ/m². Preferably, the difference between E(S2) and E(S1) and/or the difference between E(S2) and E(Pol) are at least 2 J/m², or even at least 3 J/m², even more preferably at least 10 J/m².

This enables to easily implement the final step of the method, that is, step d) of separation of the second substrate 200 and of thermoplastic polymer film 303.

Thus, during step d), when the first substrate 100 is separated from the second substrate 200, for example by inserting a wedge into the assembly, the interface having the lowest adhesion opens up. It is the interface between the anti-adherent layer 220 of the second substrate 200 and the third polymer film 303. The third polymer film 303 is thus separated from the second substrate 200. The first substrate 100 is thus covered with a thick polymer film 303. The second substrate 200, covered with anti-adherent layer 220, can be directly reused in a new cycle.

During step d), the spaces between the raised elements 110 covering the first substrate 100 are filled at least partially, if not completely, by the third thermoplastic polymer film 303.

For example, as shown in FIGS. 1E to 1G and FIGS. 2E to 2G, the method may comprise, after step d), the following steps:
implementing step b) by forming a fourth thermoplastic polymer film 304 having a thickness Ep4 on the second substrate 200, and more particularly on anti-adherent layer 220 (FIGS. 1E and 2E),
carrying out step c), by bonding the first substrate 100 and the second substrate 200 by thermocompression, whereby a fifth polymer film 305 having a thickness Ep5=Ep3+Ep4 is formed between substrates 100, 200 (FIGS. 1F and 2F),
carrying out disassembly step d) to separate the second substrate 200 from the fifth polymer film 305 (FIGS. 1G and 2G).

The cycle can be repeated until a polymer film of the desired thickness is obtained, the film thickness increasing with each cycle performed.

It is also possible to deposit the thermoplastic polymer films on only one of the first substrate 100 or of the second substrate 200. This alternative embodiment is advantageous to form a thick film on a substrate 100 covered with raised elements 110. It is in particular possible to carry out the following steps:
providing a first substrate 100, preferably covered with raised elements 110,
depositing a first polymer film 301 on a second substrate 200 comprising a support substrate 210 covered by an anti-adherent layer 220,
assembling by thermocompression the first substrate 100 and the second substrate 200, by placing into contact the first substrate 100 and the first polymer film 301,
separating the first substrate 100 from the second substrate 200, whereby a first substrate 100 having its upper surface covered by the first polymer film 301, as described in the previously-described step a), is obtained,
implementing one or a plurality of times the cycle of previously-described steps b), c) and d).

The spaces between the raised elements 110 covering the first substrate 100 are thus filled with a polymer film having a homogeneous thickness.

This method is particularly advantageous for the filling of raised structures, in particular paved structures (for example shown in FIGS. 2A to 2G). The very large chip thickness (greater than 100 μm) makes it impossible to fill the space between chips by a conventional spreading of polymer. By using the method, it is possible to progressively fill this space by repeating the cycle of spreading, bonding, and separation steps.

The resulting structure may then be subjected to a mechanical abrasion step, possibly followed by a chemical-mechanical abrasion step, for example, to have all the raised elements at the same height. These steps are easy to carry out, since the spaces between chips are filled with thermoplastic polymer.

### ILLUSTRATIVE AND NON-LIMITING EXAMPLES

The following examples are formed by means of silicon wafers having a 200-mm diameter. The surface energies are estimated by Owens and Wendt's method (J. Appl. Polym. Sci 13 (1969), 1741-1747) based on three liquids: water, ethylene glycol, and diiodomethane. The adhesion is measured by the cleavage method provided by Maszara et al (J. Appl. Phys. 64 (10), 1988).

### Example 1

A first film of polymer 301 marketed by Brewer Sciences under reference BrewerBOND® BB305 is spread on a silicon wafer 100. Film 301 has a 40-μm thickness.

There is then deposited on a silicon wafer 210 a fluorinated film 200 from a solution marketed by NOVEC (3M) under reference EGC 1720 to form the second substrate 200. The surface energy of the EGC 1720 film is 11 mJ/m².

A second polymer film 302 of BrewerBOND® BB305 polymer adhesive, having a 40-μm thickness, is spread over the second substrate 200.

The two substrates 100, 200 are bonded together at a 250° C. temperature and a 15-kN force to form a third film 303. The adhesion of the interface between the third film 303 of BrewerBOND® BB305 and the first substrate 100 is 2 J/m². The adhesion between the third film 303 of Brewer 305 and the anti-adherent layer 220 of EGC 1720 is 0.2 J/m².

A wedge is inserted into the resulting structure and the second substrate is disassembled, the third Brewer 305 film 303 remains bonded to the surface of the first substrate 100. A third 80-μm film 303 of BrewerBOND® BB305, is obtained on the surface of the first substrate 100.

A fourth film of 40-μm Brewer BB305 polymer 304 is spread again over the second substrate 200.

Substrates 100, 200 are bonded at a 250° C. temperature and a 15-kN force to form a fifth film 305.

A wedge is inserted into the structure and the second substrate 200 is disassembled, Brewer BB305 film 305 remains at the surface of the first substrate 100. A 120-μm Brewer BB305 film 305 is obtained at the surface of the first substrate 100. S1 is then bonded at 210° C. and a 6-kN force to a silicon wafer covered with silicon pads having a 80-μm height, a 10×10 mm² surface area, and spaced apart by 5 mm. The bonded structure is flawless.

### Example 2

A first polymer film 301 of BrewerBOND® BB305, having a 40-μm thickness, is spread on a silicon wafer 100.

There is deposited on a silicon wafer 210 an anti-adherent film of octadecyltrichlorosilane (OTS, marketed by Sigma-Aldrich) 220. The deposition is carried out from a solution of OTS in isooctane. A second substrate 200 is thus obtained. The surface energy of OTS film 220 is 17 mJ/m².

There is spread on the second substrate 200 a second 40 μm-thick film of BrewerBOND® BB305 polymer adhesive 302. The two substrates 100, 200 are bonded at a 250° C. temperature and a 15-kN force. A third film 303 is formed between the two substrates 100, 200. The adhesion of the interface between the third film 303 of BrewerBOND® BB305 and the first substrate 100 is 2 J/m². The adhesion between BrewerBOND® BB305 and the anti-adherent layer 220 of the second substrate 200 is 0.2 J/m².

A wedge is inserted into the structure and the second substrate 200 is disassembled, the third Brewer adhesive film 303 305 remains at the surface of the first substrate 100. A 80-μm Brewer film 305 is obtained at the surface of the first substrate 100.

### Example 3

There is spread on a wafer 100 a first Zero Newton TWM12000 adhesive film 301 having a 100-μm thickness.

There is deposited on a silicon wafer 210 a film of perfluorodecyltrichlorosilane (FDTS, marketed by Sigma-Aldrich) dissolved in isooctane to form an anti-adherent layer 220. A second substrate 200 is thus obtained. The surface energy of FDTS film 220 is 10 mJ/m².

There is spread on the second substrate 200 a second 100-μm Zero Newton TWM12000 adhesive film 302.

The two substrates 100, 200 are bonded at 240° C. and a 20-kN force, whereby a third film 303 is formed between the two substrates 100, 200. The adhesion of the interface between the third TWM12000 film 303 and the first substrate 100 is 3,000 mJ/m². The adhesion between the third TWM12000 film 303 and the FDTS anti-adherent layer 220 of the second substrate 200 is 900 mJ/m².

A wedge is inserted into the structure and the second substrate 200 is disassembled, the TWM12000 adhesive 303 remains at the surface of the first substrate 100. A third polymer film 303 having a 200-μm thickness is obtained.

By further repeating the operations of spreading of TWM12000 onto the second substrate 200, of bonding to the first substrate 100, and of disassembly of the second substrate 200 4 times, the first substrate 100 is coated with a 600 μm-thick Zero Newton TWM12000 film.

### Example 4

One takes a first substrate 100 formed of a wafer having square chips 110, with a 3-mm side length and a 650-μm thickness, bonded thereto. Chips 110 are spaced apart by 1 mm.

A second substrate 200 is formed by depositing on a silicon support substrate 210 an anti-adherent film 220 of perfluorodecyltrichlorosilane (FDTS, marketed by Sigma-Aldrich) dissolved in isooctane. The surface energy of the FDTS 220 film is 10 mJ/m².

There is spread on the second substrate 200 a second adhesive film 302 made of 100 μm-thick TOK TWM12000.

The second substrate 200 is bonded to the first substrate 100 at 240° C. and a 20-kN force. A third adhesive film 303 is obtained. The adhesion of the interface between the third TWM12000 film 303 and the first substrate is 3,000 mJ/m². The adhesion between the third TWM12000 film 303 and the FDTS anti-adherent layer 220 is 900 mJ/m².

A wedge is inserted into the structure and the second substrate 200 is disassembled. The third adhesive film 303 made of TWM12000 remains at the surface of the first substrate 100. A polymer film 303 of approximately 400 μm is obtained between the chips, since the support of the bonding guides the polymer into the trenches. Some ten microns of polymer remain on the surface of the chips.

By further repeating the operations of spreading of the TWM12000 polymer film on the second substrate 200, of bonding to the first substrate 100, and of removal of the second substrate 200, the trenches between the chips covering the first substrate 100 are filled with polymer.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. Method for producing a polymer film of high thickness on a substrate comprising the following steps:
a) forming a first thermoplastic polymer film on a first substrate covered by raised elements,
b) forming a second thermoplastic polymer film on a second substrate, the second substrate comprising a support substrate covered by an anti-adherent layer,
c) bonding the second thermoplastic polymer film to the first thermoplastic polymer film by thermocompression, by applying a creep temperature higher than the glass transition temperature of the first thermoplastic polymer film and of the second thermoplastic polymer film, whereby a third thermoplastic polymer film is obtained,
d) separating the first substrate from the second substrate, the third thermoplastic polymer film separating from the anti-adherent layer and remaining on the first substrate.

2. Method according to claim 1, wherein steps b) to d) are repeated one or a plurality of times until a thermoplastic polymer film having the desired thickness is obtained.

3. Method according to claim 1, wherein the first thermoplastic polymer film and the second thermoplastic polymer film are selected, independently of each other, from among polyolefin, polyamide, polyethylene terephthalate, or ethylene vinyl acetate copolymer films.

4. Method according to claim 1, wherein the raised elements, for example chips or pillars, have a thickness of at least 80 μm and, even more preferably, of at least 100 μm.

5. Method according to claim 1, comprising, after step d), a subsequent step of mechanical abrasion, possibly followed by a step of chemical-mechanical abrasion, on the raised elements.

6. Method according to claim 1, wherein the anti-adherent layer is a halogenated polymer layer, preferably, a fluoropolymer layer.

7. Method according to claim 1, wherein the anti-adherent layer is a layer formed of silane compounds, preferably halosilanes, for example an octadecyl-trichlorosilane layer or a perfluorodecyltrichlorosilane layer.

8. Method according to claim 1, wherein the first substrate and/or the support substrate of the second substrate are made of glass or of a semiconductor material, for example of silicon.

9. Method according to claim 1, wherein the creep temperature is higher by at least 100° C. than the glass transition temperature of the first thermoplastic polymer film and than the glass transition temperature of the second thermoplastic polymer film.

10. Method according to claim 1, wherein, on the one hand, the adhesion energy between the anti-adherent layer and the third thermoplastic polymer film is lower by at least 500 mJ/m² than the adhesion energy between the first thermoplastic polymer film and the second thermoplastic polymer film and, on the other hand, the adhesion energy between the anti-adherent layer and the third thermoplastic polymer film is lower by at least 500 mJ/m² than the adhesion energy between the first substrate and the third thermoplastic polymer film.

11. Method according to claim 1, wherein, at step d), the spaces between the raised elements covering the first substrate are filled at least partially, if not completely, by the third thermoplastic polymer film.
